(19) United States
(12) Patent Application Publication
(10) Pub. No.: US 2020/0219443 A1
(43) Pub. Date: Jul. 9, 2020

(54) ORGANIC LIGHT EMITTING DIODE DISPLAY PANEL

(71) Applicant: Wuhan China Star Optoelectronics Semiconductor Display Technology Co., Ltd., Wuhan (CN)

(72) Inventors: Kaixiang ZHAO, Wuhan (CN); Di Li, Wuhan (CN)

(21) Appl. No.: 16/492,129

(22) PCT Filed: Apr. 24, 2019
(86) PCT No.: PCT/CN2019/084066

§ 371 Date: Sep. 8, 2019

(30) Foreign Application Priority Data
Dec. 6, 2018 (CN) 201811489532.0

(51) Int. Cl. G09G 3/3233; H01L 27/32

(52) U.S. Cl. CPC G09G 3/3233; H01L 27/3262; G09G 2320/0233; H01L 27/3276; H01L 27/3265

(57) ABSTRACT

An OLED display panel includes subpixels, scanning lines, data lines, a scanning signal output unit, and a data signal output unit. Each subpixel includes a storage capacitor. In the same row of subpixels, the farther a distance away from the scanning signal output unit is, the greater a capacitance value of the storage capacitor in the subpixel is. In the same column of subpixels, the farther a distance away from the data signal output unit is, the greater a capacitance value of the storage capacitor in the subpixel is. The capacitance value of the storage capacitor of the subpixel farther from the data signal output unit is greater in the same column of subpixels. The voltage change caused by the voltage drop is balanced by changing the capacitance value of the storage capacitor, thereby improving the uniformity of the display screen.

### BACKGROUND

### 1. Field of the Disclosure

The present disclosure relates to display technology, and more particularly, to an organic light emitting diode (OLED) display panel.

### 2. Description of the Related Art

A flat display device, with advantages of high definition, energy saving, thin body, radiation-free, wide range of application, etc., are widely applied to a variety of consumer electronics such as cellphones, televisions (TVs), personal digital assistants (PDAs), digital cameras, notebook computers, and desktop computers.

With features of self-illumination, no backlight, high contrast, thin thickness, wide viewing angle, fast response, applicable to a flexible panel, wide temperature range, simple structure and process, an OLED display device is considered to be emerging application technologies for next-generation flat panel displays.

The OLED display device generally includes a substrate, an anode disposed on the substrate, a hole injection layer disposed on the anode, a hole transport layer disposed on the hole injection layer, a light-emitting layer disposed on the hole transport layer, an electron transport layer on the light-emitting layer, an electron injection layer arranged on the electron transport layer, and a cathode arranged on the electron injection layer. The luminescent principle of OLED display devices is that semiconductor materials and organic luminescent materials are driven by electric fields, causing luminescence by carrier injection and recombination. An OLED display device usually adopts an indium oxide (ITO) pixel electrode and a metal electrode as an anode and an cathode of the device, respectively, driven by a certain voltage. Electrons and holes are injected from the cathode and the anode to the electron transport layer and the hole transport layer, respectively. Electrons and holes migrate to the light-emitting layer through the electron transport layer and the hole transport layer, respectively, and meet in the light-emitting layer to form excitation. The luminescent molecules are excited and then emit visible light through radiation relaxation.

With the advancement of the times and technology, large-size, high-resolution AMOLED display devices have gradually developed. Large-size AMOLED display devices also require a greater display panel and a greater number of pixels. But, the length of the signal lines in the display panel will be greater and greater. The resistors of a signal line resistance is greater and greater as well. Inevitably, the signal applied to the signal line generates an IR drop, causing the signal actually applied to each subpixel to deviate from the original signal. Finally, the subpixel brightness is insufficient, and the display panel uniformity is lowered.

### SUMMARY

An object of the present disclosure is to propose an OLED display panel with an advantage of display uniformity.

According to the present disclosure, an organic light emitting diode (OLED) display panel, includes a plurality of subpixels, a plurality of scanning lines, a plurality of data lines, a scanning signal output unit, and a data signal output unit. The plurality of subpixels arranged in an array. Each row of the subpixels is correspondingly provided with a scanning line electrically connected to the row of the subpixels. Each column of the subpixels is correspondingly provided with a data line electrically connected to the column of the subpixels. The scanning signal output unit is electrically connected to the plurality of scanning lines. The data signal output unit is electrically connected to the plurality of data lines. Each of the plurality of subpixels comprises a storage capacitor. In the same row of subpixels, the farther a distance away from the scanning signal output unit is, the greater a capacitance value of the storage capacitor in the subpixel is. In the same column of subpixels, the farther a distance away from the data signal output unit is, the greater a capacitance value of the storage capacitor in the subpixel is.

According to an embodiment of the present disclosure, each of the plurality of storage capacitors comprises a first electrode plate and a second electrode plate arranged at intervals in parallel. The distance between the first electrode in the storage capacitor and the second electrode plate in the storage capacitor is equal. In the same row of subpixels, a facing area between the first electrode plate and the second electrode plate in the storage capacitor of the subpixel is greater as long as the distance between the scanning signal output unit and the subpixel is greater. In the same column of subpixels, a facing area between the first electrode plate and the second electrode plate in the storage capacitor of the subpixel is greater as long as the distance between the data signal output unit and the subpixel is greater.

According to an embodiment of the present disclosure, each of the subpixels further comprises a switch thin film transistor (TFT), a drive TFT, and an OLED. A gate of the switch TFT is electrically connected to the scanning line which the subpixel corresponds to. A source of the switch TFT is electrically connected to the data line which the subpixel corresponds to. A drain of the switch TFT is electrically connected to the gate of the drive TFT and the first electrode plate of the storage capacitor. The source of the drive TFT is electrically connected to the second electrode plate of the storage capacitor and a power supply voltage. The drain of the drive TFT is electrically connected to an anode of the OLED. A cathode of the OLED is grounded.

According to an embodiment of the present disclosure, the gate of the switch TFT, the gate of the drive TFT, the scanning line, and the first electrode plate of the storage capacitor are all located in the first metal layer. The source of the switch TFT, the drain of the switch TFT, the source of the drive TFT, the drain of the drive TFT, the data line, and the second electrode plate of the storage capacitor are all located in a second metal layer where an insulating layer is laminated on the first metal layer.

According to an embodiment of the present disclosure, two of the scanning signal output units are adopted; two terminals of each of the scanning lines are electrically connected to the two scanning signal output units, respectively. A capacitance value of the storage capacitor of each of the subpixels in the same row gradually decreases from the middle of the row of the subpixels to both terminals of the row of the subpixels.

According to an embodiment of the present disclosure, one of the scanning signal output units is adopted; one terminal of each of the scanning lines is electrically connected to the scanning signal output unit. A capacitance value of the storage capacitor of each of the subpixels in the same row gradually increases from one terminal of the row of the subpixels near the scanning signal output unit to the other terminal of the row of the subpixels away from the scanning signal output unit.

According to an embodiment of the present disclosure, one of the data signal output units is adopted; one terminal of each of the data lines is electrically connected to the data signal output unit. The capacitance value of the storage capacitor of each of the subpixels in the same column gradually increases from one terminal of the column of the subpixels near the data signal output unit to the other terminal of the column of the subpixels away from the data signal output unit.

According to an embodiment of the present disclosure, the first electrode plate and the second electrode plate of the storage capacitor are formed with two mask processes, respectively.

According to an embodiment of the present disclosure, an adjustment of the facing area between the first electrode plate of each of the storage capacitors and the second electrode plate of each of the storage capacitors is a change of an opening size of a mask adopted in the mask process.

According to an embodiment of the present disclosure, the first metal layer and the second metal layer are both made of molybdenum, aluminum, copper, or a combination of molybdenum, aluminum, and copper.

An OLED display panel of the present disclosure includes a plurality of subpixels, a plurality of scanning lines, a plurality of data lines, a scanning signal output unit, and a data signal output unit. The plurality of subpixels arranged in an array. Each row of the subpixels is correspondingly provided with a scanning line electrically connected to the row of the subpixels. Each column of the subpixels is correspondingly provided with a data line electrically connected to the column of the subpixels. The scanning signal output unit is electrically connected to the plurality of scanning lines. The data signal output unit is electrically connected to the plurality of data lines. Each of the plurality of subpixels comprises a storage capacitor. In the same row of subpixels, the farther a distance away from the scanning signal output unit is, the greater a capacitance value of the storage capacitor in the subpixel is. In the same column of subpixels, the farther a distance away from the data signal output unit is, the greater a capacitance value of the storage capacitor in the subpixel is. An advantageous effect brought by the present disclosure is as follows. The capacitance value of the storage capacitor of the subpixel farther from the data signal output unit is greater in the same column of subpixels. The voltage change caused by the voltage drop is balanced by changing the capacitance value of the storage capacitor, thereby improving the uniformity of the display screen.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a schematic diagram of an OLED display panel according to a first embodiment of the present disclosure.

FIG. 2 illustrates a schematic diagram of an OLED display panel according to a second embodiment of the present disclosure.

FIG. 3 illustrates a circuit diagram of a subpixel of an OLED display panel according to the present disclosure.

FIG. 4 illustrates a structural diagram of the subpixel of an OLED display panel according to the present disclosure.

FIG. 5 depicts a relationship between a drain current and a gate voltage applied on the TFT of the OLED display panel according to the present disclosure.

### DETAILED DESCRIPTION OF THE EMBODIMENTS

For the purpose of description rather than limitation, the following provides such specific details as a specific system structure, interface, and technology for a thorough understanding of the application. However, it is understandable by persons skilled in the art that the application can also be implemented in other embodiments not providing such specific details.

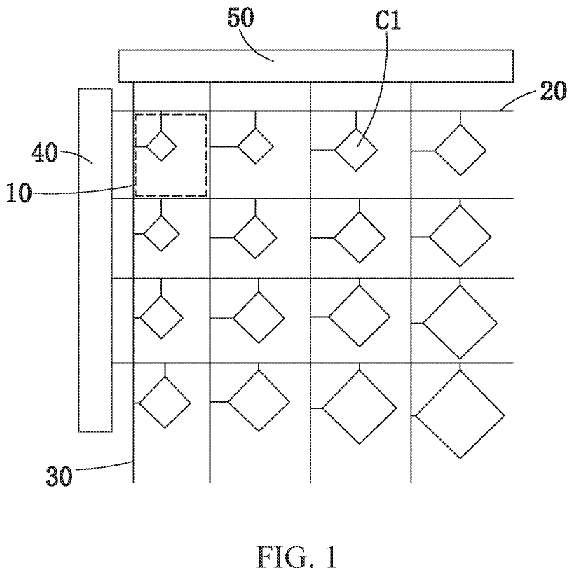

Please refer to FIG. 1 to FIG. 4. An organic light emitting diode (OLED) display panel is proposed by a first embodiment of the present disclosure. The OLED display panel includes a plurality of subpixels 10, a plurality of scanning lines 20, a plurality of data lines 30, a scanning signal output unit 40, and a data signal output unit 50.

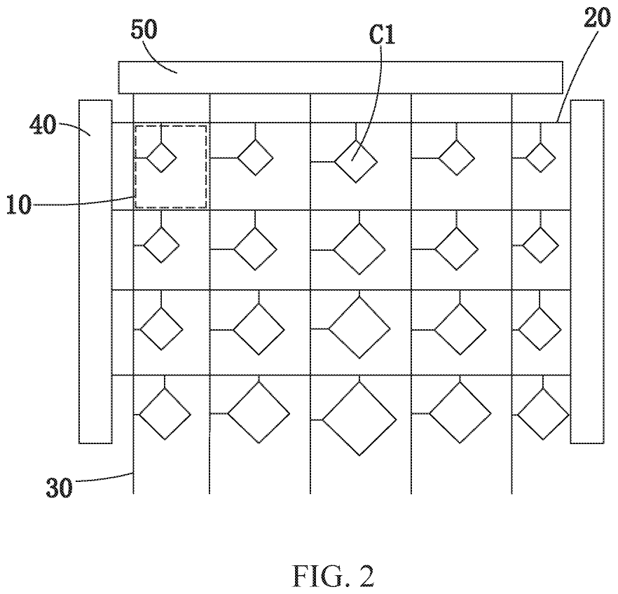

As illustrated in FIG. 1 or FIG. 2, a plurality of subpixels 10 are arranged in an array, and a plurality of scanning lines 20 are insulated from the plurality of data lines 30 to form a plurality of closed patterns. The plurality of subpixels 10 are disposed in the plurality of closed patterns, respectively. Each row of subpixels 10 are correspondingly provided with a scanning line 20 electrically connected to the row of subpixels 10. Each column of subpixels 20 are correspondingly provided with a data line 30 electrically connected to the column of subpixels 10. The scanning signal output unit 40 is electrically connected to the plurality of scanning lines 20. The data signal output unit 50 is electrically connected to the plurality of data lines 30.

Each of the subpixels 10 includes a storage capacitor C1. In the same row of subpixels 10, the capacitance value of the storage capacitor C1 in the subpixel 10 farther from the scanning signal output unit 40 is greater. In the same column of subpixels 10, the capacitance value of the storage capacitor C1 in the subpixel 10 farther from the data signal output unit 50 is greater.

Each of the subpixels 10 in the OLED display panel requires a drive thin film transistor (drive TFT) T2 to drive the OLED D1 to emit light. The storage capacitor C1 is configured to store a data voltage for controlling the opening of the drive TFT T2 so that the drive TFT T2 can be smoothly turned on and a current can be input to the OLED D1 to drive the OLED D1 to emit light.

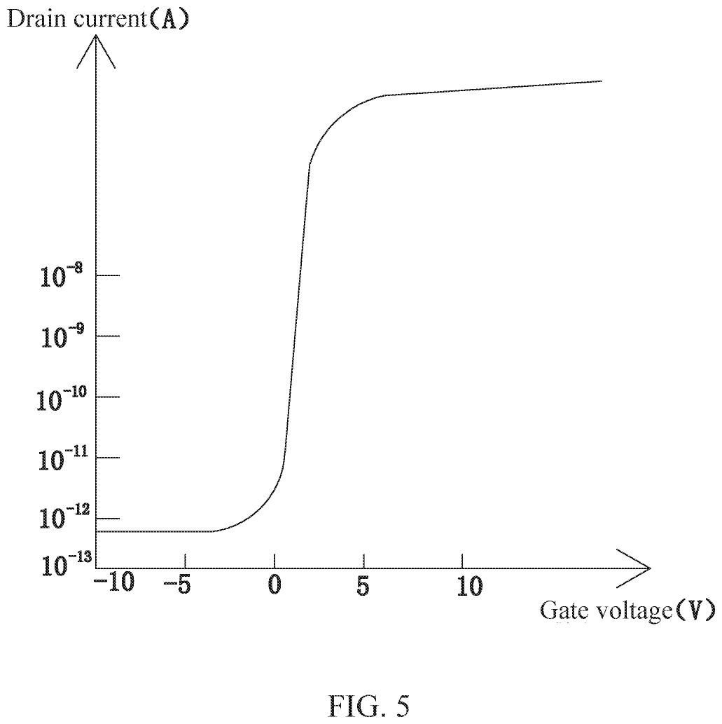

FIG. 5 illustrates the relationship between the gate voltage applied on the N-type TFT and the drain current. The higher the gate voltage is, the greater the drain current becomes.

The capacitance value of the storage capacitor C1 in each of the subpixels 10 can be adjusted so that different voltages may be imposed on the storage capacitor C1 of the different subpixels 10, thereby changing the gate voltage of the drive TFT T2 and affecting the current flowing through the drive TFT T2. A small storage capacitor in a subpixel with a small voltage drop results in a large storage capacitor in a subpixel with a large voltage drop. A change in a capacitance value of the storage capacitor balances a voltage change due to a voltage drop, finally causing an inflow of the current to the OLED D1 to be the same, which ensures the uniformity of the display.

Only one scanning signal output unit 40 is adopted, as illustrated in FIG. 1. One terminal of each of the scanning lines 20 is electrically connected to the scanning signal output unit 40. The capacitance value of the storage capacitor C1 of each of the subpixels 10 in the same row gradually increases from one terminal of the row of subpixels 10 near the scanning signal output unit 40 to the other terminal of the row of subpixels 10 away from the scanning signal output unit 40.

Only one data signal output unit 50 is adopted. One terminal of each of the data lines 30 is electrically connected to the data signal output unit 50.

The capacitance value of the storage capacitor C1 of each of the subpixels 10 in the same row gradually increases from one terminal of the row of subpixels 10 near the data signal output unit 50 to the other terminal of the row of subpixels 10 away from the data signal output unit 50.

As illustrated in FIG. 2, two scanning signal output units 40 are adopted in a second embodiment of the present disclosure. Two terminals of each scanning lines 20 are electrically connected to the two scanning signal output units 40, respectively.

The capacitance value of a storage capacitor C1 of each of the subpixels 10 in the same row gradually decreases from the middle of the row of subpixels 10 to both terminals of the row of subpixels 10.

Only one data signal output unit 50 is adopted. One terminal of each data line 30 is electrically connected to a data signal output unit 50.

The capacitance value of the storage capacitor C1 of each of the subpixels 10 in the same column gradually increases from one terminal of the column of subpixels 10 near the data signal output unit 50 to the other terminal of the column of subpixels 10 away from the data signal output unit 50.

Specifically, the capacitance value of each of the storage capacitors C1 is changed by adjusting the facing area of the electrode plate in each of the storage capacitors C1. Each of the storage capacitors C1 includes a first electrode plate 61 and a second electrode plate 62 which are disposed in parallel at intervals.

The distance between the first electrode plate 61 and the second electrode plate 62 in the storage capacitor C1 in all the subpixels 10 is equal.

In the same row of subpixels 10, the facing area between the first electrode plate 61 and the second electrode plate 62 in the storage capacitor C1 of the subpixel 10 is greater as long as the distance between the scanning signal output unit 40 and the subpixel 10 is greater.

In the same column subpixel 10, the facing area between the first electrode plate 61 and the second electrode plate 62 of the storage capacitor C1 in the subpixel 10 is greater as long as the distance between the data signal output unit 50 and the subpixel 10 is greater.

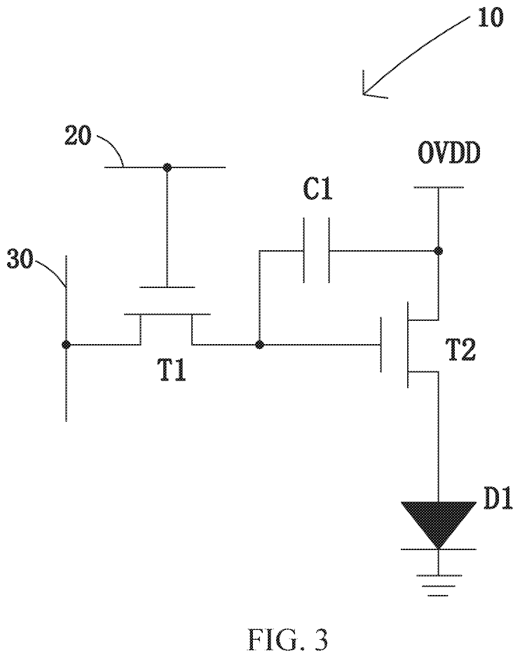

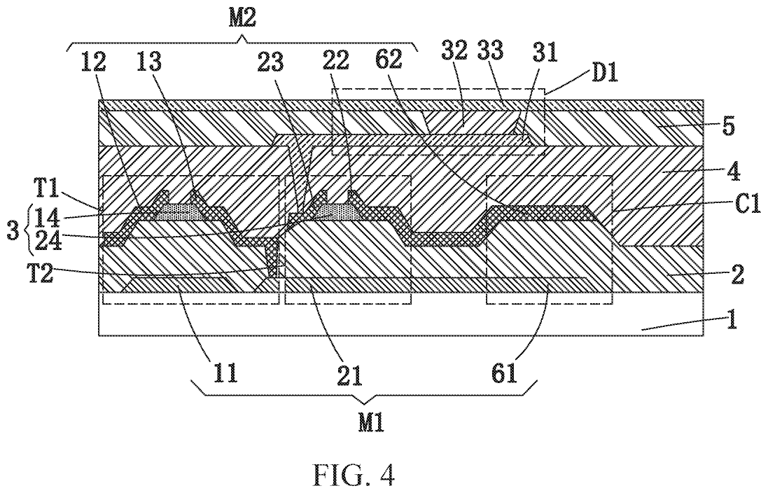

FIG. 3 and FIG. 4 illustrate each subpixel 10 including a switch thin film transistor (TFT) T1, a drive TFT T2, an organic light emitting diode (OLED) D1, and a storage capacitor C1 according to another embodiment of the present disclosure.

The gate 11 of the switch TFT T1 is electrically connected to the scanning line 20 which the subpixel 10 corresponds to. A source 12 is electrically connected to the data line 30 which the subpixel 10 corresponds to. A drain 13 is electrically connected to a gate 21 of the drive TFT T2 and the first electrode plate 61 of the storage capacitor C1.

A source 22 of the drive TFT T2 is electrically connected to the second electrode plate 62 of the storage capacitor C1 and a power supply voltage Vdd. A drain 23 is electrically connected to an anode 31 of the OLED D1.

A cathode 33 of the OLED D1 is grounded.

As illustrated in FIG. 4, an organic light emitting diode (OLED) display panel includes a substrate 1, a first metal layer M1, a gate insulating layer 2, an active layer 3, a second metal layer M2, a passivation layer 4, an anode 31, a pixel defining layer 5, a light-emitting layer 33, and a cathode 33 according to another embodiment of the present disclosure. The first metal layer M1 is arranged on the substrate 1. The second metal layer M2 is arranged on the first metal layer M1. The active layer 3 is arranged on the gate insulating layer 2. The second metal layer M2 is arranged on the active layer 3 and the gate insulating layer 2. The passivation layer 4 is arranged on the second metal layer M2. The anode 31 is arranged on the passivation layer 4. The pixel defining layer 5 is arranged on the anode 31 and the passivation layer 4. The light-emitting layer 33 is arranged on the anode 31. The cathode 33 is arranged on the light-emitting layer 33 and the pixel defining layer 5.

The first metal layer M1 includes the gate 11 of the switch TFT T1, the gate 21 of the drive TFT T2, and the first electrode plate 61 of the storage capacitor C1. The gate 21 is spaced apart from the gate 11 of the switch TFT T1. The first electrode plate 61 is electrically connected to the gate 21 of the drive TFT T2.

The active layer 3 includes an active layer 14 of the switch TFT T1 and an active layer 24 of the drive TFT T2. The active layer 14 of the switch TFT T1 is arranged on the gate insulating layer 2 on the gate 11 of the switch TFT T1. The active layer 24 of the drive TFT T2 is arranged on the gate insulating layer 2 on the gate 21 of the drive TFT T2.

The second metal layer M2 includes the source 12 of the switch TFT T1, the drain 13 of the switch TFT T1 , the source 22 of the TFT T2, the drain 23 of the TFT T2, and the second electrode plate 62 of the storage capacitor C1. The source 12 of the switch TFT T1 and the drain 13 of the switch TFT T1 are connected with both terminals of the active layer 14 of the switch TFT T1, respectively. The source 22 of the TFT T2 and the drain 23 of the TFT T2 are connected with both terminals of the active layer 24 of the drive TFT T2, respectively.

The anode 31, the cathode 33, and the light-emitting layer 33 collectively form an OLED D1.

The first electrode plate 61 and the second electrode plate 62 of the storage capacitor C1 are formed with two mask processes, respectively. Based on the above embodiment, the two mask processes are respectively a mask process for patterning the first metal layer M1 and a mask process for patterning the second metal layer M2. An adjustment of the facing area between the first electrode plate 61 of each of the storage capacitors C1 and the second electrode plate 62 of each of the storage capacitors C1 is a change of the opening size of a mask adopted in the mask process. Specifically, the size of the opening of the area where the first electrode plate 61 and the second electrode plate 62 are formed corresponding to the mask process. The facing area of the first electrode plate 61 and the second electrode plate 62 of the storage capacitor C1 is adjusted such that the first electrode plate 61 and the second electrode plate 62 of the storage capacitor C1 in the subpixel 10 with a small voltage drop are directly opposite each other. The first electrode plate 61 and the second electrode plate 62 of the storage capacitor C1 in the subpixel 10 with a small area and a large voltage drop obtain a large opposing area. In this way, the capacitance value of the first electrode plate 61 and the second electrode plate 62 of the storage capacitor C1 in the subpixel 10 with a small voltage drop is small. The capacitance value of the first electrode plate 61 and the second electrode plate 62 of the storage capacitor C1 in the subpixel 10 with a large voltage drop is large.

The first metal layer M1 and the second metal layer M2 are both made of molybdenum, aluminum, copper, or a combination of molybdenum, aluminum, and copper. Consequently, an OLED display panel of the present disclosure includes a plurality of subpixels, a plurality of scanning lines, a plurality of data lines, a scanning signal output unit, and a data signal output unit. The plurality of subpixels arranged in an array. Each row of the subpixels is correspondingly provided with a scanning line electrically connected to the row of the subpixels. Each column of the subpixels is correspondingly provided with a data line electrically connected to the column of the subpixels. The scanning signal output unit is electrically connected to the plurality of scanning lines. The data signal output unit is electrically connected to the plurality of data lines. Each of the plurality of subpixels comprises a storage capacitor. In the same row of subpixels, the farther a distance away from the scanning signal output unit is, the greater a capacitance value of the storage capacitor in the subpixel is. In the same column of subpixels, the farther a distance away from the data signal output unit is, the greater a capacitance value of the storage capacitor in the subpixel is. An advantageous effect brought by the present disclosure is as follows. The capacitance value of the storage capacitor of the subpixel farther from the data signal output unit is greater in the same column of subpixels. The voltage change caused by the voltage drop is balanced by changing the capacitance value of the storage capacitor, thereby improving the uniformity of the display screen.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

What is claimed is:

1. A an organic light emitting diode (OLED) display panel, comprising: a plurality of subpixels arranged in an array, a plurality of scanning lines, a plurality of data lines, a scanning signal output unit, and a data signal output unit;
each row of the subpixels being correspondingly provided with a scanning line electrically connected to the row of the subpixels; each column of the subpixels being correspondingly provided with a data line electrically connected to the column of the subpixels; the scanning signal output unit being electrically connected to the plurality of scanning lines; the data signal output unit being electrically connected to the plurality of data lines;
wherein each of the plurality of subpixels comprises a storage capacitor; in the same row of subpixels, the farther a distance away from the scanning signal output unit is, the greater a capacitance value of the storage capacitor in the subpixel is; in the same column of subpixels, the farther a distance away from the data signal output unit is, the greater a capacitance value of the storage capacitor in the subpixel is.

2. The OLED display panel according to claim 1, wherein each of the plurality of storage capacitors comprises a first electrode plate and a second electrode plate arranged at intervals in parallel;
the distance between the first electrode in the storage capacitor and the second electrode plate in the storage capacitor is equal;
in the same row of subpixels, a facing area between the first electrode plate and the second electrode plate in the storage capacitor of the subpixel is greater as long as the distance between the scanning signal output unit and the subpixel is greater;
in the same column of subpixels, a facing area between the first electrode plate and the second electrode plate in the storage capacitor of the subpixel is greater as long as the distance between the data signal output unit and the subpixel is greater.

3. The OLED display panel according to claim 2, wherein each of the subpixels further comprises:
a switch thin film transistor (TFT), comprising a gate electrically connected to one of the scanning lines, a source electrically connected to one of the data lines;
a drive TFT, comprising a gate electrically connected to a gate of the switch TFT and the first electrode plate of the storage capacitor, and a source electrically connected to the second electrode plate of the storage capacitor and a power supply voltage; and
an OLED, comprising an anode electrically connected to a drain of the drive TFT, and a cathode grounded.

4. The OLED display panel according to claim 3, wherein the gate of the switch TFT, the gate of the drive TFT, the scanning line, and the first electrode plate of the storage capacitor are all located in the first metal layer;
the source of the switch TFT, the drain of the switch TFT, the source of the drive TFT, the drain of the drive TFT, the data line, and the second electrode plate of the storage capacitor are all located in a second metal layer where an insulating layer is laminated on the first metal layer.

5. The OLED display panel according to claim 3, wherein two of the scanning signal output units are adopted; two terminals of each of the scanning lines are electrically connected to the two scanning signal output units, respectively;
a capacitance value of the storage capacitor of each of the subpixels in the same row gradually decreases from the middle of the row of the subpixels to both terminals of the row of the subpixels.

6. The OLED display panel according to claim 1, wherein one of the scanning signal output units is adopted; one terminal of each of the scanning lines is electrically connected to the scanning signal output unit;
a capacitance value of the storage capacitor of each of the subpixels in the same row gradually increases from one terminal of the row of the subpixels near the scanning signal output unit to the other terminal of the row of the subpixels away from the scanning signal output unit.

7. The OLED display panel according to claim 1, wherein one of the data signal output units is adopted; one terminal of each of the data lines is electrically connected to the data signal output unit;
the capacitance value of the storage capacitor of each of the subpixels in the same column gradually increases from one terminal of the column of the subpixels near the data signal output unit to the other terminal of the column of the subpixels away from the data signal output unit.

8. The OLED display panel according to claim 2, wherein the first electrode plate and the second electrode plate of the storage capacitor are formed with two mask processes, respectively.

9. The OLED display panel according to claim 8, wherein an adjustment of the facing area between the first electrode plate of each of the storage capacitors and the second electrode plate of each of the storage capacitors is a change of an opening size of a mask adopted in the mask process.

10. The OLED display panel according to claim 4, wherein the first metal layer and the second metal layer are both made of molybdenum, aluminum, copper, or a combination of molybdenum, aluminum, and copper.
